(19) United States
(12) Patent Application Publication
(10) Pub. No.: US 2005/0160215 A1
(43) Pub. Date: Jul. 21, 2005

(54) Flow through asynchronous elastic FIFO apparatus and method for implementing multi-engine parsing and authentication

(75) Inventors: Daniel Frank Moertl, Rochester, MN (US); Dennis David Reetz, St. Charles, MN (US); Donald James Ziebarth, Rochester, MN (US)

Correspondence Address: IBM CORPORATION;ROCHESTER IP LAW DEPT. 917, 3605 HIGHWAY 52 NORTH, ROCHESTER, MN, 55901-7829, US

(73) Assignee: INTERNATIONAL BUSINESS MACHINES CORPORATION, ARMONK, NY (US)

(21) Appl. No.: 10/760,446

(22) Filed: Jan. 20, 2004

(51) Int. Cl. G11C 5/00

(52) U.S. Cl. 711/1

(57) ABSTRACT

A flow through asynchronous elastic first-in, first-out (FIFO) apparatus and method are provided for implementing multi-engine parsing and authentication. A FIFO random access memory (RAM) has a data input for receiving data and control information and a data output for outputting the data and control information. The FIFO RAM includes a plurality of locations for storing a plurality of words, each word including a set number of bits. Write clocked logic is provided for loading the data and control information to the FIFO RAM at a first clock frequency. Asynchronous read clocked logic is provided for outputting the data and control information from the FIFO RAM at a second clock frequency. The first clock frequency of the write clocked logic and the second clock frequency of the asynchronous read clocked logic and a data width of the FIFO RAM are selectively provided for outputting the data and control information from the FIFO RAM with no back pressure.

### 1. FIELD OF THE INVENTION

The present invention relates generally to the data processing field, and more particularly, relates to a flow through asynchronous elastic first-in, first-out (FIFO) apparatus and method for implementing multi-engine parsing and authentication.

### 2. DESCRIPTION OF THE RELATED ART

IO adapter and bridge chips often connect to several standard interfaces. Each of these interfaces needs to run at its architected clock rate. A highly integrated chip would have many interfaces, such as, Small Computer System Interface (SCSI), serial ATA (SATA), SAS, InfiniBand (IB), Fibre Channel (FC), peripheral component interface (PCI), and double data rate 1/double data rate 2 dynamic random access memory (DDR1/DDR2 DRAM). Thus the highly integrated chip would have many different internal asynchronous boundaries between these external interfaces and hardware engines and FIFOs in the chip.

Industry pressures are forcing more interfaces into the highly integrated chips and are requiring larger buffers. For example, a redundant array of independent disks (RAID) storage controller on a chip would have one or more system busses PCI or IB or FC, a memory interface, several SAS ports or several SCSI busses.

In some known designs, a two ported FIFO typically would have been used for data flows between asynchronous boundaries in a chip, with the FIFO written with one clock and read with another clock. But, the requirement for buffer space is always increasing, and more interfaces limits use of this design. A more efficient large internal random access memory (RAM) versus many smaller two ported FIFOs would result in a smaller chip size and lower cost. However, such larger RAMs would need to support multiple engines and interfaces, but these larger RAMs only run at one clock rate.

A need exists for a mechanism to connect multiple engines between asynchronous boundaries in a chip that reduces chip complexity and wiring congestion. It is desirable to provide such a mechanism that also reduces chip size and cost.

### SUMMARY OF THE INVENTION

Principal aspects of the present invention are to provide a flow through asynchronous elastic first-in, first-out (FIFO) apparatus and method for implementing multi-engine parsing and authentication. Other important aspects of the present invention are to provide such flow through asynchronous elastic first-in, first-out (FIFO) apparatus and method for implementing multi-engine parsing and authentication substantially without negative effect and that overcome many of the disadvantages of prior art arrangements.

In brief, a flow through asynchronous elastic first-in, first-out (FIFO) apparatus and method are provided for implementing multi-engine parsing and authentication. A FIFO random access memory (RAM) has a data input for receiving data and control information and a data output for outputting the data and control information. The FIFO RAM includes a plurality of locations for storing a plurality of words, each word including a set number of bits. Write clocked logic is provided for loading the data and control information to the FIFO RAM at a first clock frequency. Asynchronous read clocked logic is provided for outputting the data and control information from the FIFO RAM at a second clock frequency. The first clock frequency of the write clocked logic and the second clock frequency of the asynchronous read clocked logic and a data width of the FIFO RAM are selectively provided for outputting the data and control information from the FIFO RAM with no back pressure.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 is a schematic diagram illustrating an exemplary flow through asynchronous elastic first-in, first-out (FIFO) apparatus for implementing multi-engine parsing and authentication in accordance with the preferred embodiment;

FIG. 2 is a schematic diagram illustrating an exemplary use of the flow through asynchronous elastic FIFO apparatus in accordance with the preferred embodiment; and

FIG. 3 illustrates exemplary data and control fields stored in a random access memory (RAM) of the flow through asynchronous elastic FIFO apparatus in accordance with the preferred embodiment.

### DETAILED DESCRIPTION OF THE PREFERRED EMBODIMENTS

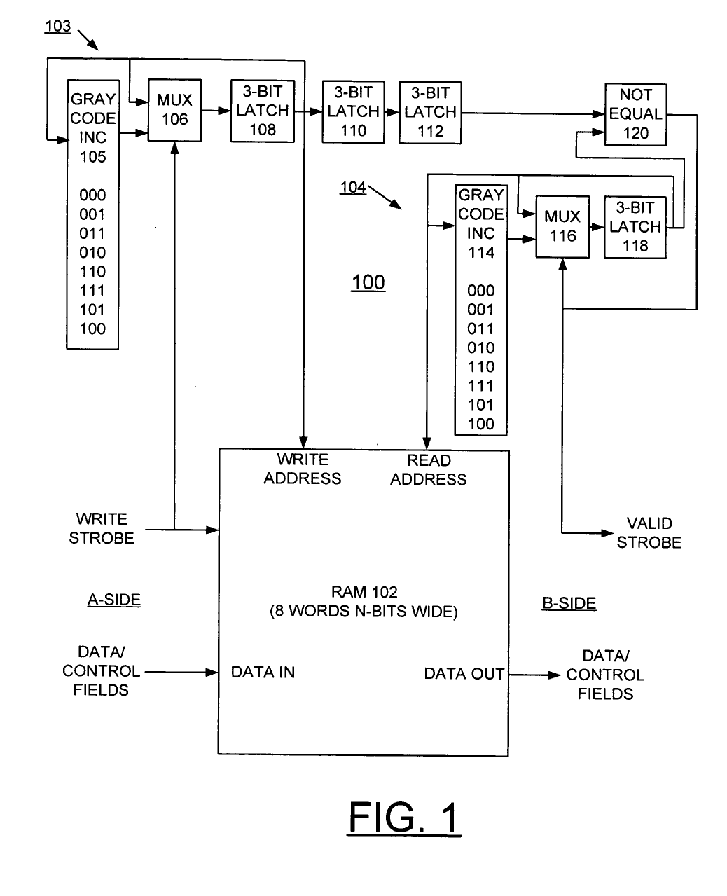

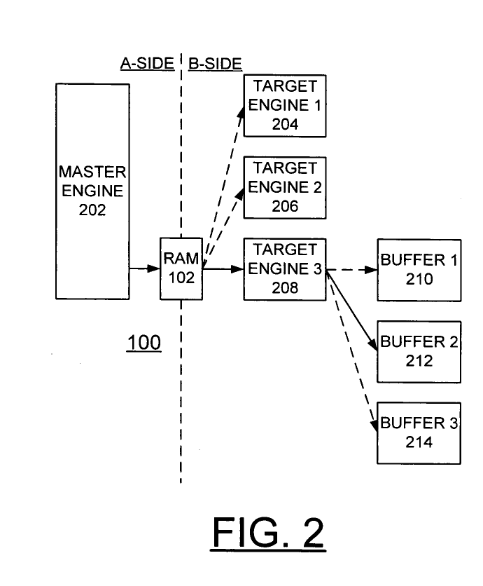

Having reference now to the drawings, in FIGS. 1, and 2, there is shown an exemplary flow through asynchronous elastic first-in, first-out (FIFO) apparatus generally designated by the reference character 100 for implementing multi-engine parsing and authentication in accordance with the preferred embodiment.

The flow through asynchronous elastic FIFO apparatus 100 includes a random access memory (RAM) 102 having a data input on an A-SIDE and a data output on a B-SIDE. The RAM 102 is used to pass a burst of data across an asynchronous boundary. The A-SIDE and the B-SIDE of the RAM 102 have different clock frequencies.

In accordance with features of the preferred embodiment, data and control fields are applied to the data input on the A-SIDE and output from the data output on a B-SIDE of RAM 102. The flow through asynchronous elastic FIFO apparatus 100 includes an A-SIDE clocked write logic generally designated by the reference character 103 and a B-SIDE asynchronous read logic generally designated by the reference character 104.

The A-SIDE clocked write logic 103 includes a Gray code increment (INC) block 105 having an input and output applied to a multiplexer (MUX) 106. The Gray code INC 105 encodes a write address input to RAM 102. As shown, the Gray code INC 105 encodes the write address with only one bit changes from one state to next state. The output of the multiplexer 106 is applied to a first latch 108 coupled to a pair of synchronization latches 110, 112 of the A-SIDE clocked write logic 103. The latch 108 provides the write address input to RAM 102 when a WRITE STROBE is received. The WRITE STROBE also causes the latch 108 to increment via the Gray code INC 105 and multiplexer 106. When WRITE STROBE is active, multiplexer 106 selects the new value from the Gray code INC 105 instead of the hold value from latch 108. The pair of synchronization latches 110, 112 avoids instability and provides synchronization with two different clocks on the A-SIDE and the B-SIDE of the RAM 102 in the flow through asynchronous elastic FIFO apparatus 100.

The B-SIDE asynchronous read logic 104 includes a Gray code INC block 114, a multiplexer (MUX) 116, a latch 118, and a not equal block 120. The Gray code INC block 114 encodes a read address input to RAM 102. An input and an output of the Gray code INC block 114 are applied to the multiplexer 116. An output of the multiplexer 116 is applied to the 3-bit latch 118. A respective output of the A-SIDE second synchronization latch 112 and of the latch 118 is applied to the not equal block 120 that generates a VALID STROBE. The VALID STROBE is applied to multiplexer 116 to cause latch 118 to increment to the next value.

As shown in FIG. 1, the RAM 102 includes, for example, eight (8) words each N-bits wide. A size of 8 words was selected for the RAM 102 since more than 4 words were needed and 8 words is the smallest RAM size that is standard in ASIC chips. Three (3) bits are used for the Gray code increment blocks 105, 114, for addressing the 8 words of the RAM 102 together with corresponding 3 bit latches 108, 110, 112, and 118. It should be understood that various other sizes could be used for the RAM 102. For example, with RAM 102 including sixteen (16) words, four (4) bits would be used for the Gray code increment blocks 105, 114, for addressing the 16 words of the RAM 102.

In accordance with features of the preferred embodiment of the flow through asynchronous elastic FIFO apparatus 100, there is no back pressure on the RAM 102, for example, with the B-SIDE clock being faster than the A-SIDE clock, so the RAM only needs to be deep enough to cover the Gray code synchronization latches 110, 112.

In accordance with features of the preferred embodiment, the flow through asynchronous elastic FIFO apparatus 100 of the preferred embodiment advantageously uses a minimal amount of logic to cross an asynchronous boundary. The flow through asynchronous elastic FIFO apparatus 100 allows ASICs to use large central static RAMs (SRAMs) as buffers instead of many small register array (RA) FIFOs, thus reducing chip complexity, wiring congestion, reducing chip size and cost. The flow through asynchronous elastic FIFO apparatus 100 of the preferred embodiment passes data and control information through the asynchronous FIFO RAM 102 enabling other higher level functions, such as, interleaving multiple direct memory accesses (DMAs), and providing a clean abort/discard data function.

In accordance with features of the preferred embodiment, a single 8 location FIFO RAM 102 is used on each asynchronous boundary. Instead of just storing data in the FIFO RAM 102, data and control information are stored including a data field and control fields storing, for example, Target Address, Target buffer select, Target engine, valid data byte enables, an authorization code, and other control information into each location of the FIFO RAM 102. The flow through asynchronous elastic FIFO apparatus 100 of the preferred embodiment is arranged so that the FIFO RAM 102 can always drain faster than it can be loaded so there is no back pressure. The flow through asynchronous elastic FIFO apparatus 100 of the preferred embodiment allows an engine to drop its request before it completes and handles discarding the unused data.

For example, the A-SIDE could be a PCI Bus Control Engine that moves 8-bytes at 133 MHz and the B-SIDE could be internal logic running at 250 MHz.

If a design has the A-SIDE running faster than the B-SIDE, for example, if the A-SIDE PCI bus is running in PCI-X MODE2, 8-bytes at 266 MHz, then there are two options:

1. Double the B-SIDE clock frequency. In this case change from 250 MHz to 500 MHz for the read address logic that pulls the data from the RAM 102, so there is no back pressure.

2. Double the width of the RAM 102. In this case the RAM 102 is changed, for example, from 8-bytes of data to 16-bytes of data. Then the A-SIDE would load RAM 102 half as often (16-bytes at 133 MHz) and the B-SIDE could keep up (16-bytes at 250 MHz), so there is no back pressure.

The novel combination of the use of RAM 102, Gray code having a single bit change, and the dual synchronization latches 110, 112 across an asynchronous boundary with selected A-SIDE and B-SIDE clocks and selected RAM data width for no back pressure, and storing the multiple Control Fields in the FIFO RAM 102 enables effectively connecting multiple engines that run asynchronously.

Referring now to FIG. 2, the use of the flow through asynchronous elastic FIFO RAM apparatus 100 is illustrated with an A-SIDE master engine 202, a plurality of B-SIDE target engines 1-3, 204, 206, 208, and a plurality of buffers 1-3, 210, 212, 214 coupled to the target engine 3, 208. A Higher Level Protocol that causes a particular B-SIDE target engine 204, 206, 208 to request the A-SIDE master engine 202 to do work is not shown.

The flow through asynchronous elastic FIFO RAM apparatus 100 of the preferred embodiment enables the actual data movement between the A-SIDE master engine 202 and the B-SIDE target engines 204, 206, 208. This Higher Level Protocol passes the Control Fields to be stored with data into the RAM 102 from the B-SIDE to the A-SIDE master engine 202 before the master engine 202 starts the data burst transfer.

The master engine 202 can have many requests enqueued, the Control Fields for the currently active burst are the ones that are stored into the RAM 102 with the burst data. As shown in FIG. 2 and indicated by solid lines the target engine 3, 208 is selected and a particular buffer 2, 212 of the multiple attached buffers 1-3 210, 212, 214 is selected.

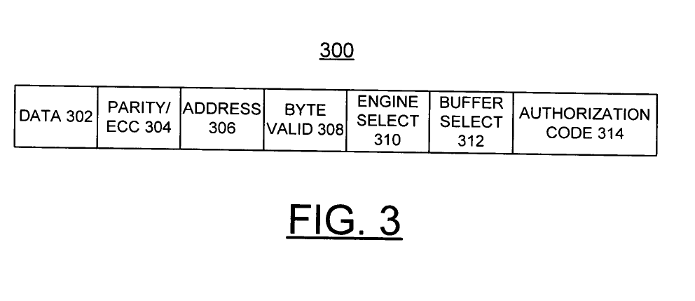

In accordance with features of the preferred embodiment, data and control information are all stored into the RAM 102 instead of just data. An exemplary Data Field and a plurality of exemplary Control Fields are illustrated and described with respect to FIG. 3.

Referring now to FIG. 3, there are shown exemplary data and control fields generally designated by reference character 300 for data and control information stored in RAM 102 of the flow through asynchronous elastic FIFO apparatus 100 in accordance with the preferred embodiment. A data field 302 is the data being DMAed through the asynchronous FIFO RAM 102. A parity or error correction code (ECC) field 304 is optional and each field can have either no protection or parity or ECC protection. Multiple fields can be combined under one parity or ECC field. This parity or ECC protection can be checked either as the DATA is read from the RAM 102, and/or by the target engines 204, 206, 208.

An address field 306 is the target engine's Buffer Address that is to be used when the B-SIDE Data Field is written. For example, address field 306 is used as a buffer address for the particular selected buffer 2, 212 attached to the illustrated selected target engine 3, 208 of FIG. 2.

A byte valid field 308 includes bits to enable a selected byte from the Data Field to be written so that all the bytes of data in the Data Field may not need to be written to the B-SIDE target engine's buffer. An optional engine select field 310 selects a particular target engine for the Data/Control Field to be sent when there is more than one target engine.

An optional buffer select field 312 selects a particular buffer for the Data/Control Field to be sent when there is more than one buffer on the target engine.

An optional authorization code field 314 is compared with a currently active Authorization Code for the target engine. When the compared codes do not match, then this Data/Control Field is discarded as it is read from the RAM 102 on the B-SIDE.

The authorization code field 314 is used, for example, when the B-SIDE target engine may have requested a DMA then later determined the data is not needed. For example, the SCSI bus could have disconnected so this prefetch data is not needed at this time. For example, the SCSI bus could have disconnected so the prefetch data is not needed at this time, while the A-SIDE ENGINE may be required to complete its full transfer. So this authorization code field 314 is used to cause the now unneeded data to be discarded without error.

The B-SIDE ENGINE will change its authorization code field 314 for each Higher Level Protocol DMA request, if only one request could be outstanding at a time, then only a singe bit would be required for this field.

While the present invention has been described with reference to the details of the embodiments of the invention shown in the drawing, these details are not intended to limit the scope of the invention as claimed in the appended claims.

1. A flow through asynchronous elastic first-in, first-out (FIFO) apparatus comprising:
a FIFO random access memory (RAM) having a data input for receiving data and control information and a data output for outputting said data and control information; said FIFO RAM including a plurality of locations for storing a plurality of words, each word including a set number of bits;
write clocked logic for loading said data and control information to said FIFO RAM at a first clock frequency;
asynchronous read clocked logic for outputting said data and control information from said FIFO RAM at a second clock frequency; and
said first clock frequency of said write clocked logic and said second clock frequency of said asynchronous read clocked logic and a data width of said FIFO RAM being selectively provided for outputting said data and control information from said FIFO RAM with no back pressure.

2. A flow through asynchronous elastic first-in, first-out (FIFO) apparatus as recited in claim 1 wherein said FIFO RAM includes a multiple location FIFO RAM used on each asynchronous boundary.

3. A flow through asynchronous elastic first-in, first-out (FIFO) apparatus as recited in claim 1 wherein loading said data and control information enables predefined higher level functions including interleaving multiple direct memory accesses (DMAs), and providing an abort and discard data function.

4. A flow through asynchronous elastic first-in, first-out (FIFO) apparatus as recited in claim 1 wherein said data and control information includes a data field storing data being direct memory accessed (DMAed) through said FIFO RAM.

5. A flow through asynchronous elastic first-in, first-out (FIFO) apparatus as recited in claim 1 wherein said data and control information includes a control field storing parity or error correction code (ECC) control information.

6. A flow through asynchronous elastic first-in, first-out (FIFO) apparatus as recited in claim 1 wherein said data and control information includes a control field storing buffer address control information for writing a data field to a buffer of a target engine.

7. A flow through asynchronous elastic first-in, first-out (FIFO) apparatus as recited in claim 1 wherein said data and control information includes a control field storing byte valid control information for writing a data byte from a data field to a buffer of a target engine.

8. A flow through asynchronous elastic first-in, first-out (FIFO) apparatus as recited in claim 1 wherein said data and control information includes a control field storing engine select control information for selecting a target engine.

9. A flow through asynchronous elastic first-in, first-out (FIFO) apparatus as recited in claim 1 wherein said data and control information includes a control field storing buffer select control information for selecting a buffer on a target engine.

10. A flow through asynchronous elastic first-in, first-out (FIFO) apparatus as recited in claim 1 wherein said data and control information includes a control field storing authorization code control information for discarding said data and control information being outputted from said FIFO RAM.

11. A flow through asynchronous elastic first-in, first-out (FIFO) apparatus as recited in claim 1 wherein said write clocked logic for loading said data and control information to said FIFO RAM at said first clock frequency includes a Gray code increment block encoding a write address input to said FIFO RAM.

12. A flow through asynchronous elastic first-in, first-out (FIFO) apparatus as recited in claim 11 includes a multiplexer coupled to said Gray code increment block and receiving a write strobe select input for incrementing a Gray code write address.

13. A flow through asynchronous elastic first-in, first-out (FIFO) apparatus as recited in claim 12 includes a pair of synchronization latches to provide a synchronization input to said asynchronous read clocked logic for outputting said data and control information from said FIFO RAM at said second clock frequency.

14. A flow through asynchronous elastic first-in, first-out (FIFO) apparatus as recited in claim 13 wherein said asynchronous read clocked logic for outputting said data and control information from said FIFO RAM at said second clock frequency includes a Gray code increment block encoding a read address input to said FIFO RAM.

15. A flow through asynchronous elastic first-in, first-out (FIFO) apparatus as recited in claim 13 wherein said asynchronous read clocked logic includes a multiplexer coupled to said Gray code increment block encoding said read address input to said FIFO RAM and receiving a valid strobe select input for incrementing a Gray code read address.

16. A method for implementing multi-engine parsing and authentication with a flow through asynchronous elastic first-in, first-out (FIFO) apparatus including a FIFO random access memory (RAM) having a data input for receiving data and a data output for outputting said data; the FIFO RAM including a plurality of locations for storing a plurality of words, each word including a set number of bits; said method comprising the steps of:
loading data and control information to the FIFO RAM at a first clock frequency;
outputting said data and control information from the FIFO RAM at a second clock frequency; and
selectively providing said first clock frequency and said second clock frequency and a data width of the FIFO RAM for outputting said data and control information from the FIFO RAM with no back pressure.

17. A method as recited in claim 16 wherein the step of loading data and control information includes the steps of storing a data field and a plurality of control fields in the FIFO RAM.

18. A method as recited in claim 17 wherein the steps of storing said plurality of control fields including storing an engine select control field for selecting a target engine.

19. A method as recited in claim 17 wherein the steps of storing said plurality of control fields including storing an authorization code control field for discarding said data and control information being outputted from the FIFO RAM.

20. A method as recited in claim 17 wherein the steps of storing said plurality of control fields including storing an address control field for writing a data field to a buffer of a target engine.

21. A method as recited in claim 17 wherein the steps of storing said plurality of control fields including storing a byte valid control field for writing a data byte from a data field to a buffer of a target engine.

22. A method as recited in claim 17 wherein the steps of storing said plurality of control fields including storing a buffer select control field for selecting a buffer of a target engine.

23. A method as recited in claim 17 wherein the steps of storing said plurality of control fields including storing a parity or error correction code (ECC) control field for providing parity of ECC protection.
